(19) United States
(12) Patent Application Publication
(10) Pub. No.: US 2008/0230886 A1
(43) Pub. Date: Sep. 25, 2008

(54) Stacked package module

(75) Inventors: Lin-Yin Wong, Hsinchu (TW); Mao-Hua Yeh, Hsinchu (TW); Wang-Hsiang Tsai, Hsinchu (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 11/976,489

(22) Filed: Oct. 25, 2007

(30) Foreign Application Priority Data
Mar. 23, 2007 (TW) 096110110

(51) Int. Cl. H01L 23/488

(52) U.S. Cl. 257/686; 257/E23.023

(57) ABSTRACT

A stacked package module is disclosed, which comprises: a first package structure comprising a first circuit board with a first chip embedded therein, wherein the first chip has a plurality of electrode pads, the first circuit board comprises a first surface, an opposite second surface, a plurality of first conductive pads on the first surface, a plurality of second conductive pads on the second surface, a plurality of conductive vias, and at least one circuit layer, and the electrodes of the first chip directly electrically connect to the conductive pads on the surfaces of the circuit board through the conductive vias and the circuit layer within the circuit board; and a second package structure electrically connecting to the first package structure through a plurality of solder balls to make package on package. The stacked package module provided by this invention has characteristics of compact size, high performance, and high flexibility.

### BACKGROUND OF THE INVENTION

1. Field of the Invention

The present invention relates to a stacked package module and, more particularly, to a stacked package module which can enhance the elasticity of conductive pad layout.

2. Description of Related Art

In the development of electronics, the design trend of electronic devices is towards multifunction and high-performance. Thus, high-density integration and miniaturization are necessary for a semiconductor package structure. On the ground of reason aforementioned, the mono-layered circuit boards providing electrical connections among active components, passive components, and circuits, are being replaced by the multi-layered circuit boards. The area of circuit layout on the circuit board increases in a restricted space by interlayer connection to meet the requirement of high-density integrated circuits.

In general, a conventional semiconductor package structure is made such that a semiconductor chip is mounted by its back surface on the top surface of the substrate, then the package structure is finished through wire bonding, or a semiconductor chip is mounted by the active surface thereof on the top surface of the substrate, thereby finishing a flip-chip package structure, followed by placing solder balls on the back surface of the substrate to provide electrical connections for an electronic device like a printed circuit board.

FIG. 1 shows a conventional wire bonding package structure. The wire bonding package structure 1 comprises a circuit board 10, a chip 11, a plurality of metal wires 14, and a molding material 15. The circuit board 10 has a first surface 10a having a plurality of wire bonding pads 101 and an opposite second surface 10b having a plurality of solder pads 102. In addition, the circuit board 10 has a cavity 105, and the chip 11 is disposed in the cavity 105. The active surface 11a of the chip 11 has a plurality of electrode pads 111, electrically connecting to the wire bonding pads 101 of the circuit board 10 by the metal wires 14. The cavity 105 of the circuit board 10 is filled with the molding material 15, and the molding material 15 wraps the chip 11 and the metal wires 14. The solder pads 102 of the circuit board 10 can electrically connect with an outer electronic device (not shown) by solder balls 16.

FIG. 2 shows a stacked package module comprising the aforementioned package structure. The stacked package module is accomplished by stacking two same package structures 1 and 1′ as shown in FIG. 1. The solder pads 102′ on the surface 10b′ of the upper package structure 1′ electrically connect with the conductive pads 103 on the surface 10a of the lower package structure 1 by a plurality of solder balls 203.

However, in the above module comprising a plurality of stacked package structures, only the remaining region of the substrate of each package structure, where no semiconductor chip is disposed, can suffice conductive pads for electrically connecting with another package structure by solder balls. It is indicated that the electrical connecting area on the substrate of each package structure is limited, and thereby the number and the layout of I/O connections of each package structure is limited, resulting in reduced elasticity of circuit layout on the substrate and design flexibility of the package structure.

Accordingly, the purpose of the present invention is to provide a package structure with a chip embedded therein and a stacked package module thereof, which has characteristics of compact size, high performance, and high flexibility.

### SUMMARY OF THE INVENTION

The object of the present invention is to provide a stacked package module where a package structure with a chip embedded therein functions as a package unit, which can provide a more compact size and space-saving product. In addition, the ball grid array area of the package structure with a chip embedded therein is not limited by the chip area so as to provide a more elastic conductive pad layout. Furthermore, the utilization of the package on package (POP) method can connect different package structures by solder balls and conductive pads to provide a package module having the function of system integration for various products.

To achieve the object, the present invention provides a stacked package module, comprising: a first package structure comprising a first circuit board with a first chip embedded therein, wherein the first chip has a plurality of electrode pads, the first circuit board comprises a first surface, an opposite second surface, a plurality of first conductive pads on the first surface, a plurality of second conductive pads on the second surface, a plurality of conductive vias, and at least one circuit layer, and the electrodes of the first chip electrically connect to the conductive pads on the surfaces of the circuit board directly through the conductive vias and the circuit layer within the circuit board; and a second package structure comprising a second chip and a second circuit board, wherein the second circuit board comprises a first surface, an opposite second surface having a plurality of second conductive pads thereon, and the second conductive pads of the second package structure electrically connect to the first conductive pads of the first package structure through a plurality of solder balls to accomplish a package module having the function of system integration. Since the first chip is embedded in the first circuit board of the first package structure, the layout of the conductive pads in a ball grid array is not limited by the chip area so as to provide a more elastic conductive pad layout.

In the stacked package module of the present invention, the first circuit board of the first package structure has a core board with a through cavity therein. The first chip is disposed in the cavity of the core board, and the gap between the core board and the first chip is filled with a filling material to fix the first chip. The first chip has an active surface and an opposite inactive surface, and the active surface has a plurality of electrode pads thereon. The first circuit board can further comprise a first built-up structure and a second built-up structure corresponding to and disposed on two sides of the core board, respectively. The first conductive pads and the second conductive pads are disposed on the surface of the first built-up structure and the surface of the second built-up structure, respectively. The first built-up structure as well as the second built-up structure comprises at least one dielectric layer, one circuit layer, a plurality of conductive vias, and a solder mask having a plurality of openings to expose the conductive pads. Some of the conductive vias electrically connect to the electrode pads of the first chip. Since the first chip is embedded in the first circuit board, the first circuit board electrically connects to the first chip through the conductive vias to thereby be employed in utilization of a chip with a more reduced pitch between electrode pads.

In the stacked package module of the present invention, the first package structure connects to the second package structure through a plurality of solder balls by a package on package method. The second package structure can be any type of package structure. Preferably, the second package structure is the same as the first package structure, flip chip package structure, wire bonding package structure, and so on.

Accordingly, the present invention provides a stacked package module wherein a package structure with a chip embedded therein functions as a package unit, which can provide a more compact size and space-saving product. In addition, since the circuit layout in the chip area of the first circuit board can be performed by the built-up structures, the ball grid array area of the package structure with a chip embedded therein is not limited by the chip area so as to provide a more elastic conductive pad layout. Furthermore, the utilization of the package on package (POP) method can connect different package structures by solder balls and conductive pads to provide a package module having the function of system integration for various products.

Other objects, advantages, and novel features of the invention will become more apparent from the following detailed description when taken in conjunction with the accompanying drawings.

### BRIEF DESCRIPTION OF THE DRAWINGS

FIG. 1 is a cross-section view of a conventional package structure;

FIG. 2 is a cross-section view of a stacked package module comprising a conventional package structure;

FIG. 3 is a cross-section view of a package structure with a chip embedded therein of a preferred embodiment of the present invention;

FIG. 4 is a top view of a package structure with a chip embedded therein of a preferred embodiment of the present invention;

FIG. 5 is a cross-section view of a stacked package module of a preferred embodiment of the present invention;

FIG. 6 is a cross-section view of a stacked package module of a preferred embodiment of the present invention;

FIG. 7 is a cross-section view of a stacked package module of a preferred embodiment of the present invention; and,

FIG. 8 is a cross-section view of a stacked package module of a preferred embodiment of the present invention.

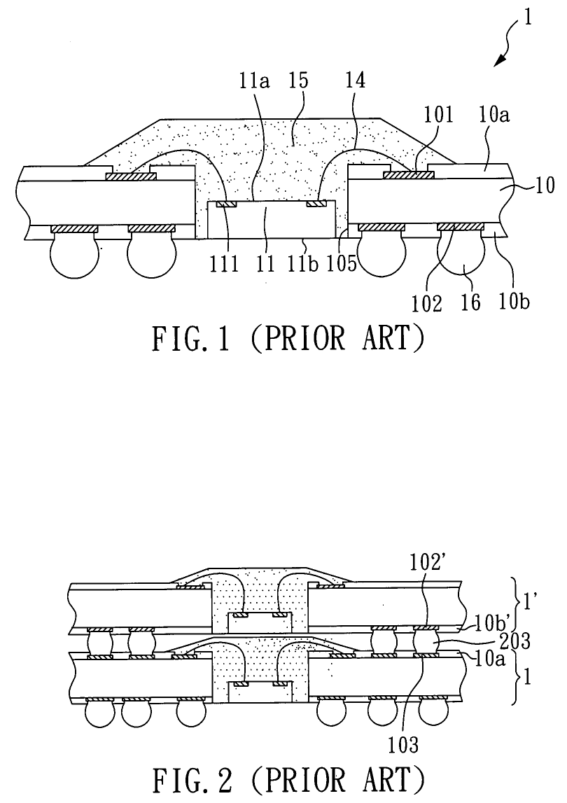

### DETAILED DESCRIPTION OF THE PREFERRED EMBODIMENT

### Embodiment 1

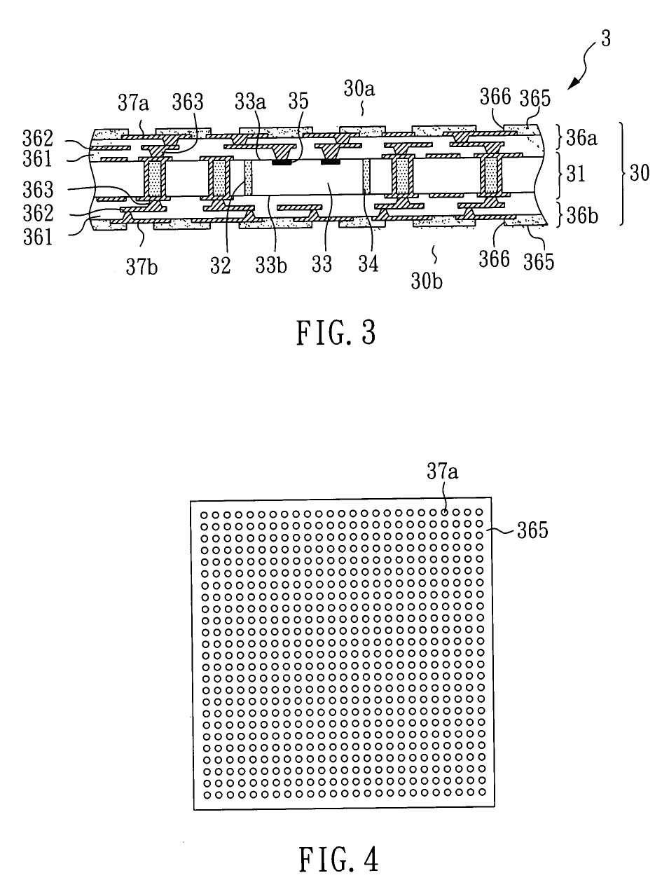

With reference to FIG. 3, there is shown a cross-section view of a package structure with a chip embedded therein. The package structure 3 with a chip embedded therein of the present embodiment comprises a first circuit board 30 with a first chip 33 embedded therein. The first circuit board 30 has a first surface 30a, an opposite second surface 30b, a plurality of first conductive pads 37a on the first surface 30a, and a plurality of second conductive pads 37b on the second surface 30b. In detail, the first circuit board 30 has a core board 31 having a through cavity 32 therein, therewith the first chip 33 disposed in the cavity 32, the gap between the core board 31 and the first chip 33 filled with a filling material 34 to fix the first chip 33, wherein the first chip 33 has an active surface 33a having a plurality of electrode pads 35 thereon and an opposite inactive surface 33b. The first circuit board 30 further has a first built-up structure 36a and a second built-up structure 36b corresponding to and disposed on two sides of the core board 31, respectively, wherein the first conductive pads 37a and the second conductive pads 37b are disposed on the surface of the first built-up structure 36a and the surface of the second built-up structure 36b, respectively, and the first built-up structure 36a as well as the second built-up structure 36b comprises at least one dielectric layer 361, at least one circuit layer 362, a plurality of conductive vias 363, and a solder mask 365 having a plurality of openings 366 to expose the conductive pads 37a as well as 37b, therewith some of the conductive vias 363 electrically connecting to the electrode pads 35 of the first chip 33. In addition, the first conductive pads 37a and the second conductive pads 37b are arranged in a ball grid array, as shown in FIG. 4, which is a top view of the package structure 3 with a chip embedded therein of the present embodiment.

The filling material 34 is selected from the group consisting of organic dielectric material, liquid organic resin, and prepreg. In the present embodiment, the filling material 34 is prepreg. In addition, the materials of the first conductive pads 37a and the second conductive pads 37b in the present embodiment are individually selected from the group consisting of copper, silver, gold, nickel/gold, nickel/palladium/gold, and the combination thereof.

### Embodiment 2

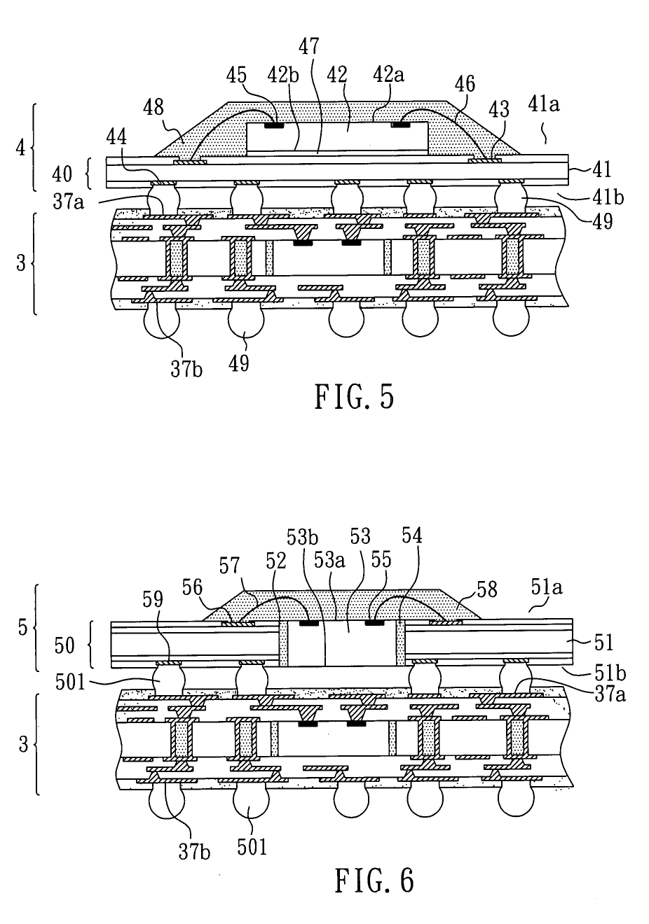

With reference to FIG. 5, there is shown a cross-section view of a stacked package module. The stacked package module of the present embodiment uses the package structure 3 of Embodiment 1 and a wire bonding package structure 4 as package units. The wire bonding package structure 4 comprises a second chip 42 and a second circuit board 40. In detail, the second circuit board 40 comprises: a substrate 41 having a first surface (for adhering a chip) 41a and an opposite second surface (for adhering solder balls) 41b; a plurality of wire bonding pads 43 disposed on the first surface 41a; and a plurality of second conductive pads 44 on the second surface 41b. The second chip 42 has an active surface 42a having a plurality of electrode pads 45 thereon and an inactive surface 42b. The electrode pads 45 of the second chip 42 electrically connect to the wire bonding pads 43 through a plurality of metal wires 46. The inactive surface of the second chip 42 is fixed on the first surface 41 a of the substrate 41 by an adhesive material 47. In addition, the wire bonding package structure 4 further comprises a molding material 48 to wrap the second chip 42 and the metal wires 46. In the stacked package module of the present embodiment, the package structure 3 connects to the package structure 4 through a plurality of solder balls 49 by a package on package method. The second conductive pads 44 of the package structure 4 electrically connect to the first conductive pads 37a of the package structure 3 by the solder balls 49. In addition, the second conductive pads 37b of the package structure 3 can also electrically connect to an outer electronic device (not shown in the figure) by the solder balls 49.

### Embodiment 3

With reference to FIG. 6, there is shown a cross-section view of a stacked package module. The stacked package module of the present embodiment uses the package structure 3 of Embodiment 1 and a wire bonding package structure 5 with a chip embedded therein as package units. The package structure 5 comprises a second chip 53 and a second circuit board 50. In detail, the second circuit board 50 comprises: a substrate 51 having a through cavity 52 therein, wherein the second chip 53 is embedded in the cavity 52, and the gap between the cavity 52 in the substrate 51 and the second chip 53 is filled with a filling material 54; a plurality of wire bonding pads 56 disposed on the first surface 51a of the second circuit board 50; and a plurality of second conductive pads 59 on the second surface 51b of the second circuit board 50. The second chip 53 has an active surface 53a and an inactive surface 53b. The active surface 53a has a plurality of electrode pads 55 thereon and is at the same side with the first surface 51a of the second circuit board 50. The electrode pads 55 of the second chip 53 electrically connect to the wire bonding pads 56 through a plurality of metal wires 57. In addition, the package structure 5 further comprises a molding material 58 to wrap the metal wires 57, the electrode pads 55 of the second chip 53 and the wire bonding pads 56 of the second circuit board 50. In the stacked package module of the present embodiment, the package structure 3 connects to the package structure 5 through a plurality of solder balls 501 by a package on package method. The second conductive pads 59 of the package structure 5 electrically connect to the first conductive pads 37a of the package structure 3 by the solder balls 501. In addition, the second conductive pads 37b of the package structure 3 can also electrically connect to an outer electronic device (not shown in the figure) by the solder balls 501.

### Embodiment 4

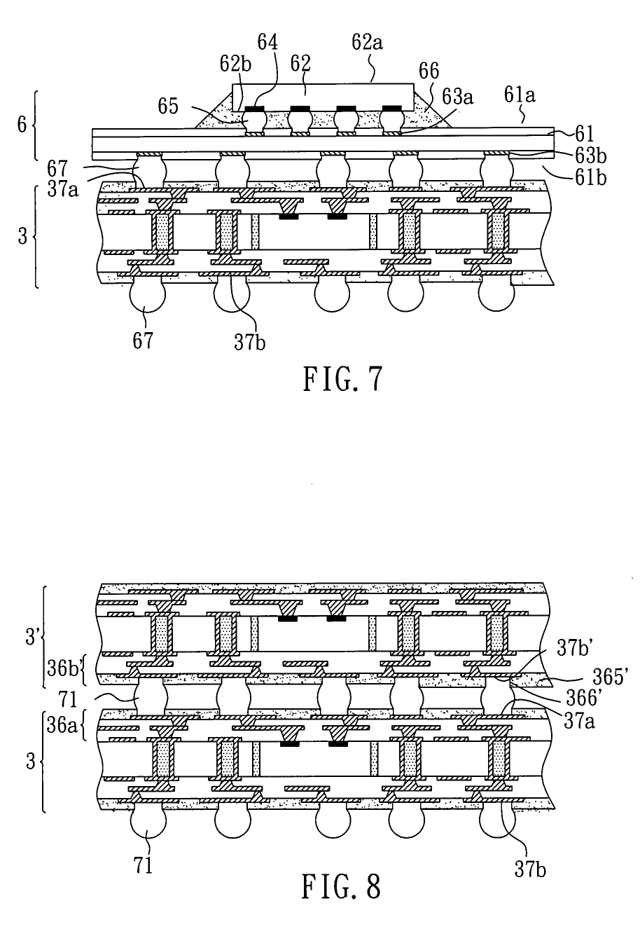

With reference to FIG. 7, there is shown a cross-section view of a stacked package module. The stacked package module of the present embodiment uses the package structure 3 of Embodiment 1 and a flip chip package structure 6 as package units. The package structure 6 comprises a second chip 62 and a second circuit board 60. In detail, the second circuit board 60 comprises: a substrate 61 having a first surface (for adhering a chip) 61a and an opposite second surface (for adhering solder balls) 61b; a plurality of first conductive pads 63a disposed on the first surface 61a of the substrate 61; and a plurality of second conductive pads 63b disposed on the second surface 61b of the substrate 61. The second chip 62 has an active surface 62b having a plurality of electrode pads 64 thereon and an inactive surface 62a. The electrode pads 64 of the second chip 62 electrically connect to the first conductive pads 63a on the first surface 61a of the substrate 61 through a plurality of solder bumps 65. In addition, the package structure 6 further comprises an underfilling material 66 disposed between the second chip 62 and the substrate 61. In the stacked package module of the present embodiment, the package structure 3 connects to the package structure 6 through a plurality of solder balls 67 by package on package method. The second conductive pads 63b of the package structure 6 electrically connect to the first conductive pads 37a of the package structure 3 by the solder balls 67. In addition, the second conductive pads 37b of the package structure 3 can also electrically connect to an outer electronic device (not shown in the figure) by the solder balls 67.

### Embodiment 5

With reference to FIG. 8, there is shown a cross-section view of a stacked package module. The stacked package module of the present embodiment uses two same package structures 3 and 3′ each with a chip embedded therein as package units. The solder mask 365′ of the second built-up structure 36b′ in the package structure 3′ has a plurality of openings 366′ to expose the second conductive pads 37b′. In the stacked package module of the present embodiment, the package structure 3 connects to the package structure 3′ through a plurality of solder balls 71 by package on package method. The second conductive pads 37b′ of the upper package structure 3′ electrically connect to the first conductive pads 37a of the lower package structure 3 by the solder balls 71. In addition, the second conductive pads 37b of the package structure 3 can also electrically connect to an outer electronic device (not shown in the figure) by the solder balls 71.

Although the present invention has been explained in relation to its preferred embodiment, it is to be understood that many other possible modifications and variations can be made without departing from the spirit and scope of the invention as hereinafter claimed.

What is claimed is:

1. A stacked package module, comprising:
a first package structure comprising a first circuit board with a first chip embedded therein, wherein the first chip has a plurality of electrode pads, the first circuit board has a first surface, an opposite second surface, a plurality of first conductive pads on the first surface, a plurality of second conductive pads on the second surface, a plurality of conductive vias, and at least one circuit layer, and the electrodes of the first chip electrically connect to the conductive pads on the surfaces of the circuit board directly through the conductive vias and the circuit layer within the circuit board; and
a second package structure comprising a second chip and a second circuit board, wherein the second circuit board comprises a first surface, an opposite second surface, and a plurality of second conductive pads on the second surface, and the second conductive pads of the second package structure electrically connect to the first conductive pads of the first package structure through a plurality of solder balls.

2. The stacked package module as claimed in claim 1, wherein the conductive pads are arranged in a ball grid array.

3. The stacked package module as claimed in claim 1, wherein the first circuit board of the first package structure comprises a core board having a through cavity therein, therewith the first chip disposed in the cavity of the core board, the gap between the core board and the first chip filled with an filling material to fix the first chip, the first chip having an active surface with a plurality of electrode pads thereon and an opposite inactive surface; the first circuit board further comprises a first built-up structure and a second built-up structure corresponding to and disposed on two sides of the core board, respectively, therewith the first conductive pads and the second conductive pads disposed on the surface of the first built-up structure and the surface of the second built-up structure, respectively, the first built-up structure as well as the second built-up structure comprising at least one dielectric layer, at least one circuit layer, a plurality of conductive vias, and a solder mask having a plurality of openings to expose the conductive pads, some of the conductive vias electrically connecting to the electrode pads of the first chip.

4. The stacked package module as claimed in claim 3, wherein the material of the filling material is selected from the group consisting of organic dielectric material, liquid organic resin, and prepreg.

5. The stacked package module as claimed in claim 1, wherein the second package structure is the same as the first package structure.

6. The stacked package module as claimed in claim 1, wherein the second package structure is a flip chip package structure.

7. The stacked package module as claimed in claim 1, wherein the second package structure is a wire bonding package structure.

8. The stacked package module as claimed in claim 1, wherein the second circuit board has a through cavity therein, therewith the second chip embedded in the cavity of the second circuit board, the gap between the cavity of the second circuit board and the second chip filled with a filling material to fix the second chip, the second chip having an active surface and an inactive surface, the active surface having a plurality of electrode pads and being at the same side with the first surface of the second circuit board, the first surface of the second circuit board further having a plurality of wire bonding pads, the electrode pads of the second chip electrically connecting to the wire bonding pads through a plurality of metal wires, and a molding material wrapping the metal wires, the electrode pads of the second chip and the wire bonding pads of the second circuit board.

9. The stacked package module as claimed in claim 8, wherein the material of the filling material is selected from the group consisting of organic dielectric material, liquid organic resin, and prepreg.

10. The stacked package module as claimed in claim 1, wherein the materials of the conductive pads are individually selected from the group consisting of copper, silver, gold, nickel/gold, nickel/palladium/gold, and the combination thereof.
